(19) United States
(12) Patent Application Publication
(10) Pub. No.: US 2012/0312347 A1
(43) Pub. Date: Dec. 13, 2012

(54) SOLAR MODULE AND PHOTOVOLTAIC ARRAY

(76) Inventor: Thomas BUETTNER, Jena (DE)

(21) Appl. No.: 13/491,340

(22) Filed: Jun. 7, 2012

(30) Foreign Application Priority Data
Jun. 8, 2011 (DE) 102011077224.3

(51) Int. Cl. H01L 31/05

(52) U.S. Cl. 136/244

(57) ABSTRACT

A solar module having a plurality of solar cells, which are interconnected to form a string and have externally accessible string connections, a bypass line having at its two ends a separate externally accessible bypass connection being integrated into the solar module.

### CROSS REFERENCE

The present application claims the benefit under 35 U.S.C. §119 of German Patent Application No. DE 102011077224.3 filed on Jun. 8, 2011, which is expressly incorporated herein by reference in its entirety.

### FIELD OF THE INVENTION

The present invention relates to a solar module having a plurality of solar cells interconnected in the form of a string, and having string connections which are accessible from the outside. In addition, it relates to a photovoltaic array having a plurality of solar modules which are electrically connected to each other.

### BACKGROUND INFORMATION

Photovoltaic modules (PV modules), often also referred to as solar modules, contain solar cells or photoelectrically active layers, which convert light into electrical current. They can be electrically contacted in order to convey the obtained electrical energy away or to interconnect a plurality of PV modules to form a larger array. The PV modules usually have a connection box for this purpose.

FIG. 1A through 1D schematically illustrate different conventional connection boxes or cable configurations. FIG. 1A schematically shows a connection box 3 having two connection contacts 3a and 3b on a solar module 1. FIG. 1B schematically shows a modified connection box 13, which has two externally mounted plug components or jacks 13a, 13b on a solar module 11, for the connection of power supply lines. FIG. 1C shows a solar module 21 having a connection box 23, to which two connection cables 25a, 25b which have a plug or jack (not denoted in particular) at their particular ends, are fixedly connected. FIG. 1D finally shows a solar module 31 having two connection boxes 33a, 33b, to which a connection cable 35a, 35b is connected, which once again has a plug or jack (not denoted in particular) at its end.

FIG. 2A through 2D show different possibilities for interconnecting solar modules to a load, i.e., a consumer or energy store or a network feeder, in the form of block diagrams. FIG. 2A shows the direct interconnection of an individual solar module 1 and a load 7; FIG. 2B shows the series connection of two solar modules la and lb to a load 7; FIG. 2C, the parallel connection of two solar modules la, lb to a load 7; and FIG. 2D, a mixed series and parallel interconnection of six solar modules 1, which jointly form a photovoltaic array 10, to a load 7.

### SUMMARY

In accordance with the present invention, the bypass connections and in particular also the string connections of a solar module are developed as plug contacts. One male and one female plug contact may be provided as bypass connections. The string connections, too, may be developed as male and female plug contacts.

In one further development, the bypass line has a band-type or wire-type conductor, which is incorporated in a sheath, in particular a foil laminate.

In a photovoltaic array having a plurality of solar modules in a series connection, the series connection according to one aspect of the present invention is formed by the interconnected, integrated bypass lines of the solar modules as return conductor.

In one development, such an array has a first connector piece, which is developed for the electrical connection of a string connection to a bypass connection of one and the same solar module. In a further embodiment, the array includes a second connector piece, which is developed for the electrical connection of an individual bypass connection of two adjacently situated solar modules. In these developments, the first and/or the second connector piece are/is developed as generally rigid plastic component having at its ends an embedded conductor and an individual connector-terminal, adapted to the connections of the solar module.

### BRIEF DESCRIPTION OF THE DRAWINGS

Further advantages and advantageous refinements of the present invention are illustrated in the figures and explained below. In this context, it should be noted that the figures have only descriptive character and are not intended to limit the present invention in any form.

FIGS. 1A-D show schematic illustrations of conventional connection options for solar modules via connection boxes.

FIGS. 2A-2D show different interconnection options of solar modules conventionally used in practice.

FIGS. 3A and 3B show schematic illustrations similar to circuit diagrams to explain the present invention or one specific development thereof.

FIG. 4 shows a perspective representation of a solar module according to this specific embodiment of the present invention.

FIG. 5 shows a perspective representation of a connector piece and the adjacent region of a solar module according to another development of the present invention.

FIG. 6 shows a schematic representation for explaining the function of the connector piece of FIG. 5.

FIG. 7 shows a perspective representation of a connector piece and the adjacent region of a solar module according to another development of the present invention.

FIG. 8 shows a schematic representation for explaining the function of the connector piece of FIG. 7.

FIG. 9 shows a perspective representation of the adjacent edge regions of two solar modules to be connected in series in a roof-integrated system, including a connection profile.

FIG. 10 shows a schematic representation to explain the structure of another photovoltaic array.

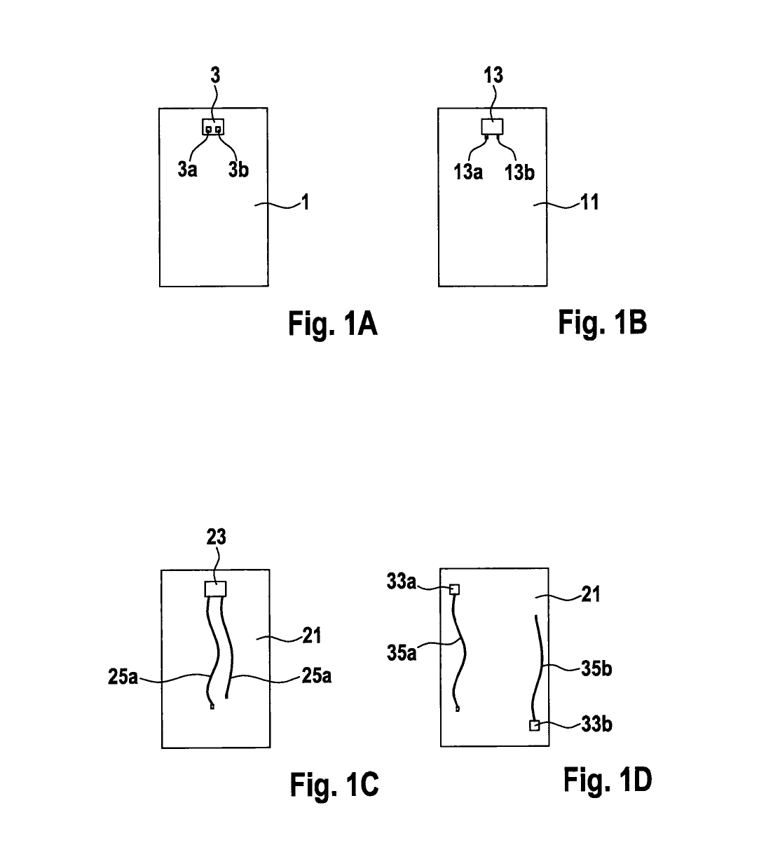

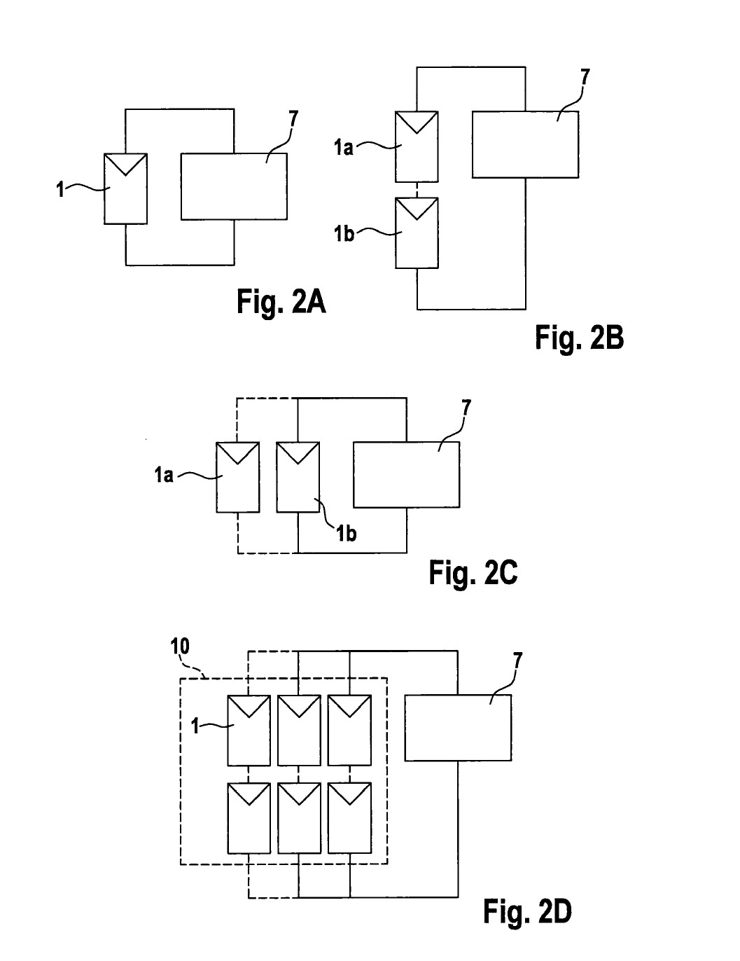

### DETAILED DESCRIPTION OF EXAMPLE EMBODIMENTS

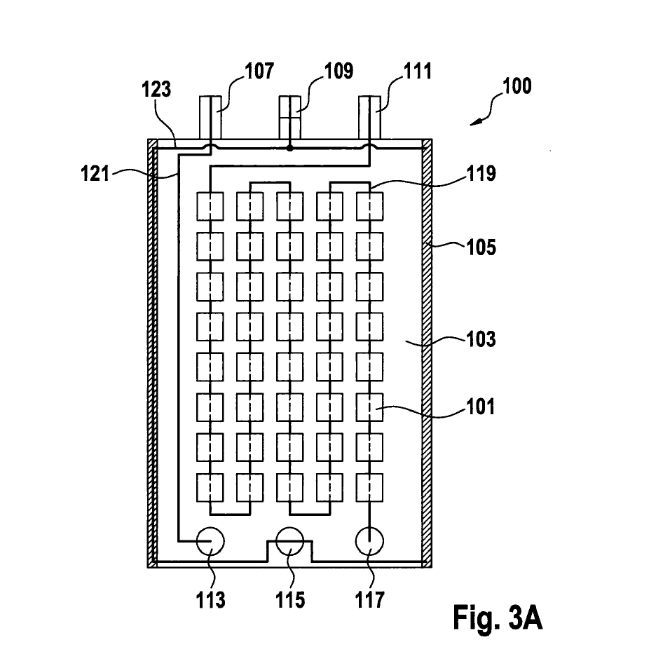

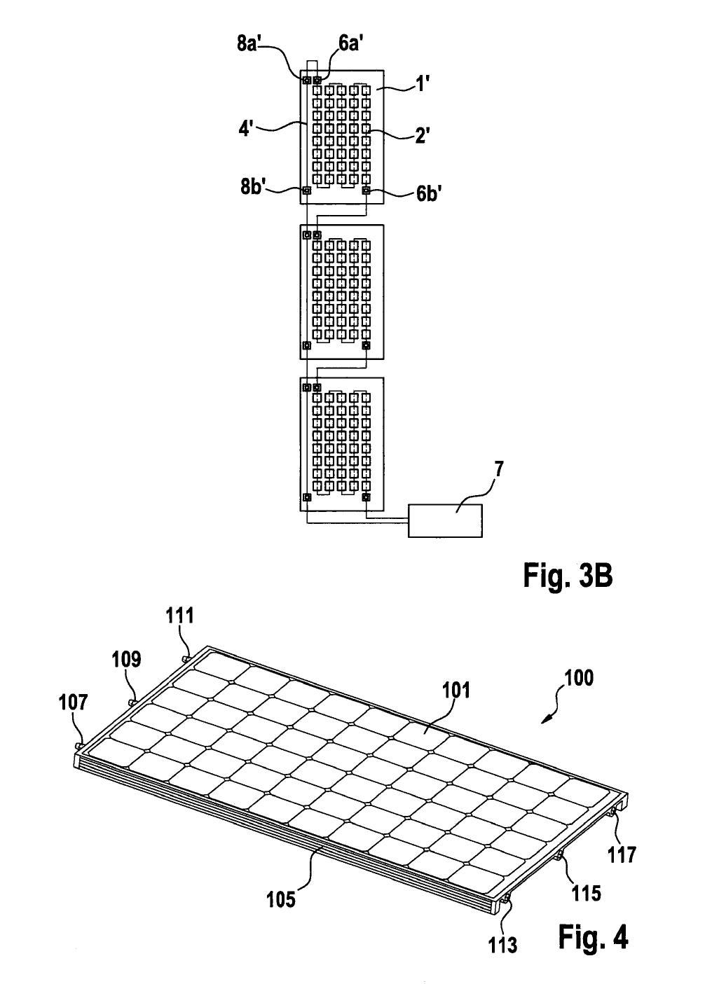

FIG. 3A schematically illustrates, in the manner of a plan view, a solar module 100, which has a multitude of solar cells 101 on a substrate 103 and includes two conductive frame profiles 105. On one of the two short edges of solar module 100, three plugs 107 through 111 are provided next to each other, i.e., a bypass plug 107, an earth plug 109, and a positive-pole plug 111. Three jacks 113 through 117 are disposed on the opposite short edge of the solar module, in a geometric arrangement that corresponds to said plugs, i.e., a bypass jack 113, an earth contact jack 115, and a negative pole jack 117. Solar cells 101 are interconnected via a first conducting track 119 and positive-pole plug 111 is connected to negative-pole jack 117 (via the solar cells). A second conducting track 121 directly connects bypass plug 107 to bypass jack 113, and a third conducting track 123 represents an earth line, which connects earth plug 109 to earth contact jack 115 together with conductive frame profiles 105.

FIG. 3 schematically illustrates a series connection of solar modules 1′, which have the afore-described structure or may also deviate from this structure, but at least include an array of solar cells 2′ interconnected to form a string, and a bypass conductor 4′ which is separate therefrom. A first and a second connection contact 6a′ and 6b′ are assigned to the solar cell strings in each case, and the bypass line also has two connection contacts 8a′ and 8b′. The suitable direct connection of the bypass contacts, as schematically illustrated in the figure and described in greater detail in the following text with reference to special connector pieces, realizes a continuous return conductor without wiring, and thus implements the desired series connection to load 7 in an especially simple and reliable manner.

FIG. 4 shows a constructive development of solar cell 100 in a perspective representation, in which the same reference numerals as in FIG. 3A have been used to denote the main components, but in which conducting tracks 119 through 123 are not visible.

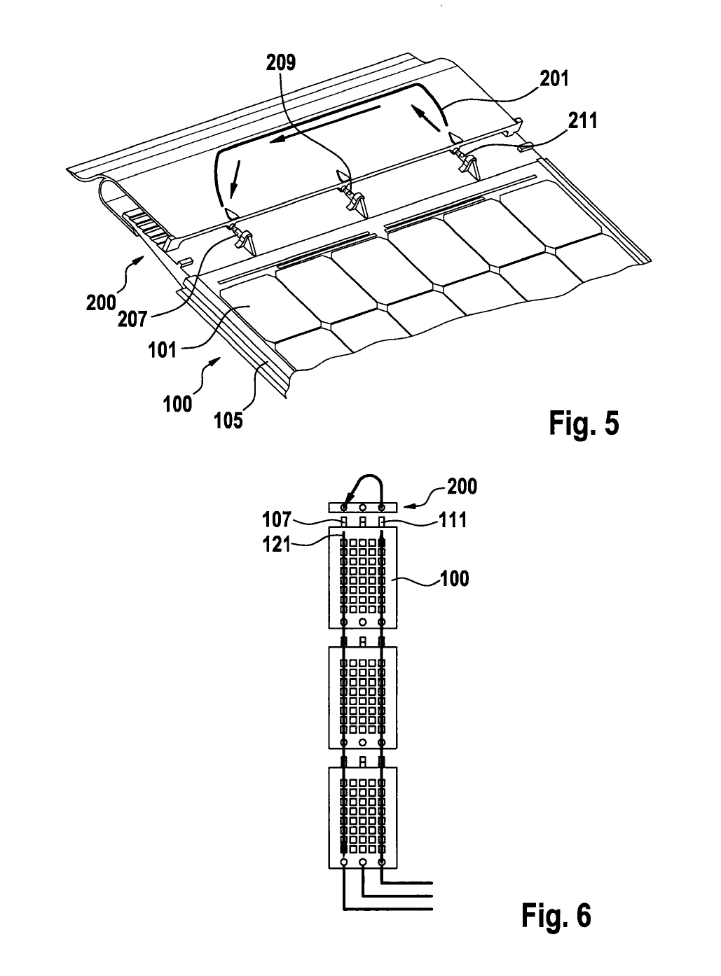

FIG. 5, as a perspective detail view, shows the region of a short edge of solar module 100 together with a connector piece 200 attached thereto, on which three plug components are disposed, which are denoted by numerals 207, 209 and 211 here, similar to the choice of reference numerals in FIG. 3. Installed between outer plug components 207 and 211, i.e., a bypass plug component and a positive-pole plug component, is a connection cable 201, which has at its end jacks (not denoted separately) that match the plugs. The figure also shows another plastic component set on top of connector piece 200, which, however, is not denoted in the figure or explained further here.

FIG. 6 schematically illustrates the function of connector piece 200 as upper termination piece in a series connection of three solar modules 100, i.e., the realization of the series connection via the connection of the positive pole of the uppermost solar module to its integrated bypass line 121.

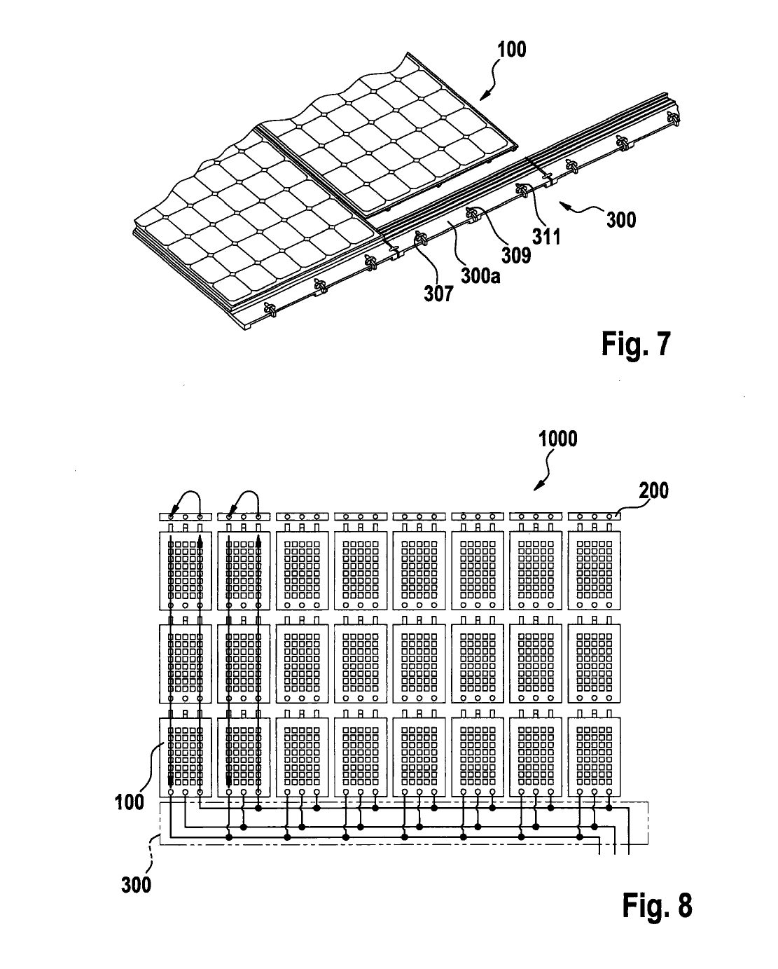

In a perspective illustration, FIG. 7 shows the (lower) short sides of two solar modules 100, which are to be interconnected in parallel in a photovoltaic array, together with a connector piece 300, which is composed of a plurality of subsections 300a in the form of an elongated profile, each including, similar to profile 200 shown in FIG. 5, a bypass plug component 307, an earth contact plug component 309, and a positive pole plug component 311. These plug components are positioned and developed to engage with the jack components of solar module 100, which are not shown here specifically for reasons of clarity.

FIG. 8 schematically illustrates the placement and internal line routing of connector piece 300 in a photovoltaic array 1000 consisting of three rows of eight solar modules 100 connected in parallel to each other in each case. The outputs on the lower right lead to the inverter of the array.

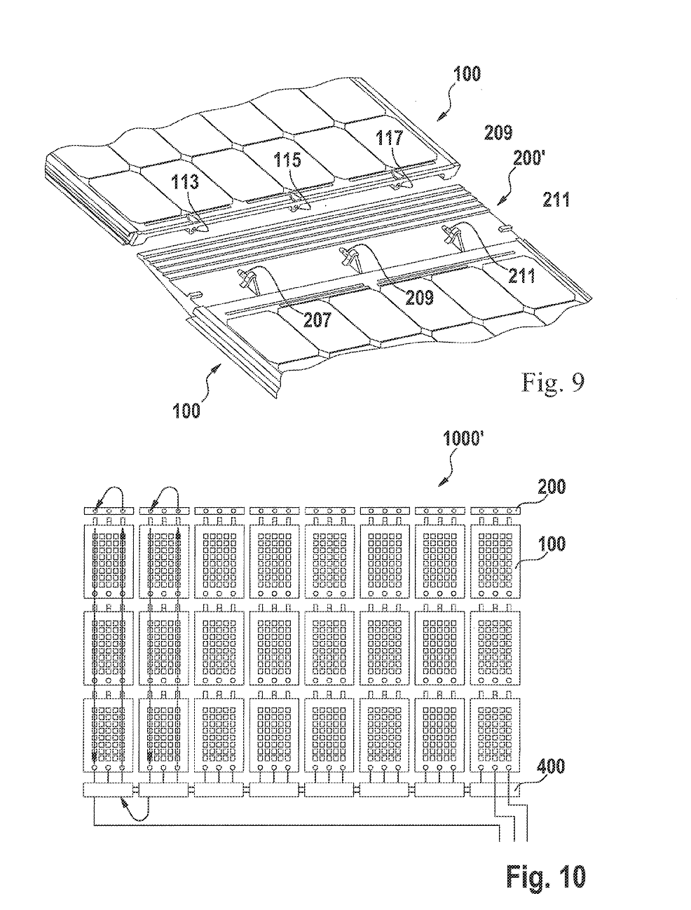

FIG. 9, in another perspective detail view, shows the short sides of two solar modules 100 to be connected in series, together with a connector piece 200′ which is modified in comparison with the development shown in FIG. 5 and differs from connector piece 200 by the omission of the integrated connection cable. When installed, plug components 207, 209 and 211 engage with correspondingly placed and formed jack components 113, 115 and 117 of the upper solar module, which ultimately causes the positive pole of the lower solar module to be connected to the negative pole of the upper solar module and the earth connections of both solar modules and their bypass connections.

FIG. 10 finally schematically shows a photovoltaic array 1000′, in which all solar modules 100 are interconnected in series; connector pieces 200 according to FIG. 5 and connector pieces 200′ (not shown here) according to FIG. 9 may be used in addition to additional connector pieces 400, which are situated at the lower edge of the array and may be constructed as a current bar system, similar to the configuration according to FIG. 7.

Additional developments and implementations of the example method and device described merely by way of example, result within the actions of one skilled in the art.

What is claimed is:

1. A solar module, comprising:
a plurality of solar cells interconnected in the form of a string, and having two externally accessible string connections; and
a bypass line, having an externally accessible bypass connection at its two ends, integrated into the solar module.

2. The solar module as recited in claim 1, wherein the bypass connections and the string connections are plug contacts.

3. The solar module as recited in claim 2, wherein one male and one female plug contact are provided as the bypass connections.

4. The solar module as recited in claim 2, wherein the bypass line has one of a band-shaped conductor or a wire-shaped conductor, and the bypass line is sheathed in a foil laminate sheath.

5. A photovoltaic array, comprising:
a plurality of solar modules in a series connection, and interconnected in a form of a string, and having two externally accessible string connections;
wherein the series connection is formed with the interconnected integrated bypass lines of the solar modules as a return conductor.

6. The photovoltaic array as recited in claim 5, further comprising:
a first connector piece for electrical connection of a string connection of one of the solar modules to a bypass connection of the same one of the solar modules.

7. The photovoltaic array as recited in claim 6, further comprising:
a second connector piece for electrical connection of an individual bypass connection of two adjacently situated solar modules of the array.

8. The photovoltaic array as recited in claim 7, wherein at least one of the first connector piece and the second connector piece is a rigid plastic component, which has at its ends an embedded conductor and a connector-terminal, adapted to connections of the solar module.
